(19) United States
(12) Patent Application Publication
(10) Pub. No.: US 2014/0231923 A1
(43) Pub. Date: Aug. 21, 2014

(54) SEMICONDUCTOR STRUCTURE AND METHOD FOR MANUFACTURING THE SAME

(71) Applicants: Huaxiang Yin, Beijing (CN); Qiuxia Xu, Beijing (CN); Dapeng Chen, Beijing (CN)

(72) Inventors: Huaxiang Yin, Beijing (CN); Qiuxia Xu, Beijing (CN); Dapeng Chen, Beijing (CN)

(73) Assignee: INSTITUTE OF MICROELECTRONICS, CHINESE ACADEMY OF SCIENCES, Beijing (CN)

(21) Appl. No.: 14/346,537

(22) PCT Filed: May 16, 2012
(86) PCT No.: PCT/CN2012/075602

§ 371 Date: Mar. 21, 2014

(30) Foreign Application Priority Data
May 3, 2012 (CN) 201210135857.5

(51) Int. Cl. H01L 27/092; H01L 21/8238

(52) U.S. Cl. CPC H01L 27/092; H01L 21/823807
USPC 257/369; 438/221

(57) ABSTRACT

The present invention provides a semiconductor structure, comprising: a substrate; a gate stack located on the substrate and comprising at least a gate dielectric layer and a gate electrode layer; source/drain regions, located in the substrate on both sides of the gate stack; an STI structure, located in the substrate on both sides of the source/drain regions, wherein the cross-section of the STI structure is trapezoidal, Sigma-shaped or inverted trapezoidal depending on the type of the semiconductor structure. Correspondingly, the present invention further to provides a method of manufacturing the semiconductor structure. In the present invention, STI structures having different shapes can be combined with different stress fillers to apply tensile stress or compressive stress laterally to the channel, which will produce a positive impact on the electron mobility of NMOS and the hole mobility of PMOS and increase the channel current of the device, thereby effectively improving the performance of the semiconductor structure.

### CROSS REFERENCE TO RELATED APPLICATIONS

This application claims the benefits of prior Chinese Patent Application No. 201210135857.5 filed on May 3, 2012, titled “SEMICONDUCTOR STRUCTURE AND METHOD FOR MANUFACTURING THE SAME”, which is incorporated herein by reference in its entirety.

### TECHNICAL FIELD

The present invention relates to the field of semiconductor technology. In particular, the present invention relates to a semiconductor structure and a method for manufacturing the same.

### BACKGROUND OF THE ART

With the development of the manufacturing technology of semiconductor devices, integrated circuits with higher performance and greater functionality require a higher component density, and the dimension, size and space of various parts, components or individual components also need to be further scaled down (which may reach the nanometer level at present). Since the 90 nm CMOS IC process, as the feature size of the device becomes smaller continuously, Strain Channel Engineering is playing an increasingly important role in improving the channel carrier mobility. Various uniaxial technology induced stresses are integrated into the device process.

Normally, the Shallow Trench Isolation (STI) process including liner forming, dielectric filling and Chemical Mechanical Polishing (CMP) planarization will induce compressive stress to adjacent active regions. It will induce compressive strain in the longitudinal direction of the device channel and subsequently, result in a mobility enhancing in PMOS and degrading in NMOS. As the device dimensions are reduced as the requirement of device scaling method, it will take a more serious effect.

To reduce this effect in the conventional STI structure, commonly used methods include low-stressed dielectric like F-doped HDP dielectric filling in STI and forming removable liner by oxidation, and the like. However, it is desirable to make a new STI structure which allows producing stress effect on both NMOS and PMOS to improve device performance.

### SUMMARY OF THE INVENTION

In order to solve the above problems, the present invention provides a semiconductor structure and a corresponding manufacturing method thereof. STI's having different cross-sectional structures according to the device types, e.g., STI's having different cross-sectional structures in the PMOS region and NMOS region are formed to introduce compressive stress and tensile stress to the channel regions of PMOS and NMOS, respectively, such that stress can be applied to both NMOS and PMOS to improve device performance.

According to one aspect of the present invention, a semiconductor structure is provided, comprising:

a substrate;

a gate stack located on the substrate, and comprising at least a gate dielectric layer and a gate electrode layer;

source/drain regions located in the substrate on both sides of the gate stack;

Shallow Trench Isolation (STI) structures located in the substrate on both sides of the source/drain regions, wherein the cross-section of the STI structures are trapezoidal, Sigma-shaped or inverted trapezoidal depending on the type of the semiconductor structure.

According to another aspect of the present invention, a method of manufacturing the semiconductor structure is provided, comprising:

providing a substrate;

forming a plurality of STI structures in the substrate to divide the substrate surface into at least one active region, wherein the cross-section of the STI structures are trapezoidal, Sigma-shaped or inverted trapezoidal depending on the type of the semiconductor structure to be formed in adjacent active regions; and

forming a gate stack and source/drain regions corresponding to the type of the semiconductor structure to be formed on a respective active region.

Compared with the prior art, the technical solution provided by the present invention has the following advantages: STI structures having different shapes can be combined with different stress fillers to apply tensile stress or compressive stress laterally to the channel, which will produce a positive impact on electron mobility of NMOS and hole mobility of PMOS and increase the channel current of the device, thereby effectively improving the performance of the semiconductor structure.

### DESCRIPTION OF THE DRAWINGS

Other characteristics, objectives and advantages of the invention will become more obvious after reading the detailed description of the non-limiting embodiments with reference to the following attached drawings, in which:

FIG. 1 is a schematic cross-sectional view after a trapezoidal trench is formed on the substrate surface by etching;

FIG. 2 is a schematic cross-sectional view after an oxide liner is formed on the trapezoidal trench surface by oxidization;

FIG. 3 is a schematic cross-sectional view after an STI is formed by filling the trapezoidal trench with oxides;

FIG. 4 is a schematic cross-sectional view after a dummy gate is formed on the substrate surface;

FIG. 5 is a schematic cross-sectional view after a source/drain junction extension is formed on both sides of the dummy gate by implantation;

FIG. 6 is a schematic cross-sectional view after a spacer is formed on both sides of the dummy gate;

FIG. 7 is a schematic cross-sectional view after a trench is formed on both sides of the dummy gate by etching;

FIG. 8 is a schematic cross-sectional view after source/drain regions and a silicide layer are formed in the trench region;

FIG. 9 is a schematic cross-sectional view after a CESL layer is formed on the surface of the device;

FIG. 10 is a schematic cross-sectional view after deposition of an interlayer dielectric layer on the surface of the device and etching planarization until the dummy gate is exposed;

FIG. 11 is a schematic cross-sectional view after the dummy gate is removed;

FIG. 12 is a schematic cross-sectional view after filling of the gate electrode material;

FIG. 13 is a schematic cross-sectional view after the second CESL layer and the second interlayer dielectric layer are deposited;

FIG. 14 is a schematic cross-sectional view after a metal plug is formed;

FIG. 15 is a schematic cross-sectional view after a Sigma-shaped trench is formed on the surface of the substrate by etching;

FIG. 16 is a schematic cross-sectional view after an oxide liner is formed on the surface of the Sigma-shaped trench by oxidization;

FIG. 17 is a schematic cross-sectional view after an STI is formed by filling the Sigma-shaped trench with oxides;

FIG. 18 is a schematic cross-sectional view after a dummy gate is formed on the surface of the substrate;

FIG. 19 is a schematic cross-sectional view after a source/drain junction extension is formed on both sides of the dummy gate by implantation;

FIG. 20 is a schematic cross-sectional view after a spacer is formed on both sides of the dummy gate;

FIG. 21 is a schematic cross-sectional view after a trench is formed on both sides of the dummy gate by etching;

FIG. 22 is a schematic cross-sectional view after source/drain regions and a silicide layer are formed on the trench region;

FIG. 23 is a schematic cross-sectional view after a CESL layer is formed on the surface of the device;

FIG. 24 is a schematic cross-sectional view after deposition of an interlayer dielectric layer on the surface of the device and etching planarization until the dummy gate is exposed;

FIG. 25 is a schematic cross-sectional view after the dummy gate is removed;

FIG. 26 is a schematic cross-sectional view after filling of the gate electrode material;

FIG. 27 is a schematic cross-sectional view after the second CESL layer and the second interlayer dielectric layer are deposited;

FIG. 28 is a schematic cross-sectional view after a metal plug is formed;

FIG. 29 is a schematic cross-sectional view after an inverted trapezoidal trench is formed on the surface of the substrate by etching;

FIG. 30 is a schematic cross-sectional view after an oxide liner to is formed by oxidization on the surface of the inverted trapezoidal trench;

FIG. 31 is a schematic cross-sectional view after an STI is formed by filling the inverted trapezoidal trench with oxides;

FIG. 32 is a schematic cross-sectional view after a dummy gate is formed on the surface of the substrate;

FIG. 33 is a schematic cross-sectional view after a source/drain junction extension is formed on both sides of the dummy gate by implantation;

FIG. 34 is a schematic cross-sectional view after a spacer is formed on both sides of the dummy gate;

FIG. 35 is a schematic cross-sectional view after a trench is formed on both sides of the dummy gate by etching;

FIG. 36 is a schematic cross-sectional view after source/drain regions and a silicide layer are formed in the trench region;

FIG. 37 is a schematic cross-sectional view after a CESL layer is formed on the surface of the device;

FIG. 38 is a schematic cross-sectional view after deposition of a interlayer dielectric layer on the surface of the device and etching planarization until the dummy gate is exposed;

FIG. 39 is a schematic cross-sectional view after the dummy gate is removed;

FIG. 40 is a schematic cross-sectional view after filling of the gate electrode material;

FIG. 41 is a schematic cross-sectional view after the second CESL layer and the second interlayer dielectric layer are deposited; and

FIG. 42 is a schematic cross-sectional view after a metal plug is formed.

### DETAILED DESCRIPTION OF THE INVENTION

Exemplary embodiments of the present disclosure will be described in more details.

Some embodiments are illustrated in the attached drawings, in which the same or similar reference numbers represent the same or similar elements or the components having the same or similar functions. The following embodiments described with reference to the drawings are only exemplary for explaining the present invention, and therefore shall not be construed as limiting the present invention. The disclosure below provides many different embodiments or examples to implement different structures of the present invention. In order to simplify the disclosure of the present invention, components and settings of specific examples are described below. Obviously, they are merely exemplary, and are not intended to limit the present invention. In addition, reference numbers and/or letters can be repeated in different examples of the invention. This repetition is used only for brevity and clarity, and does not indicate any relationship between the discussed embodiments and/or settings. Furthermore, the invention provides a variety of specific examples of processes and materials, but it is obvious to a person skilled in the art that other processes can be applied and/or other materials can be used. In addition, the following description of a structure where a first feature is “on” a second feature can comprise examples where the first and second features are in direct contact, and also can comprise examples where additional features are formed between the first and second features so that the first and second features may not be in direct contact.

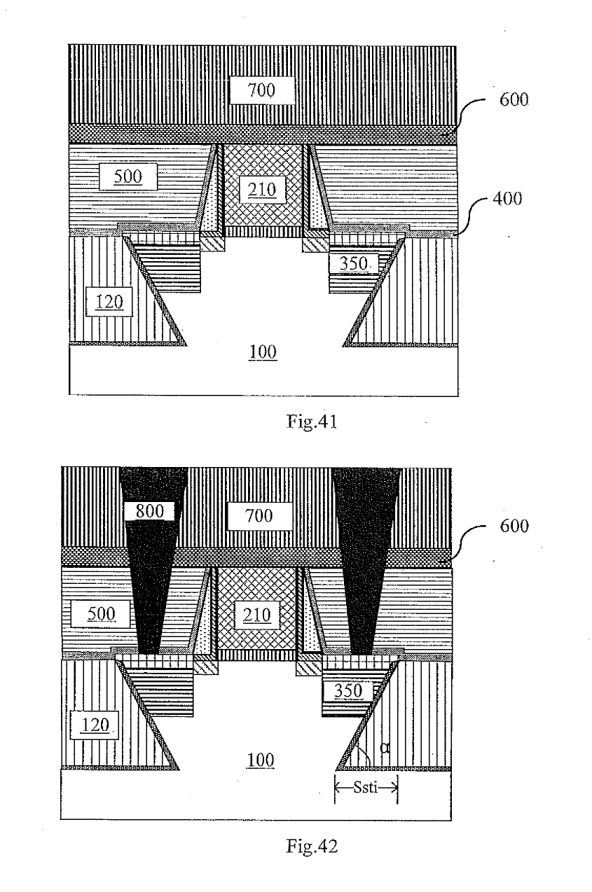

According to one aspect of the invention, a semiconductor structure is provided (please refer to the cross-sectional views in FIGS. 14, 28 and 42). As shown in the figures, the semiconductor structure comprises: a substrate 100; a gate stack located on the substrate 100 and comprising at least a gate dielectric layer and a gate electrode layer; source/drain regions 350 located in the substrate 100 on both sides of the gate stack; an STI structure 120 located in the substrate on both sides of the source/drain regions 350, wherein the cross-section of the STI structure is trapezoidal (see FIG. 14), Sigma-shaped (see FIG. 28) or inverted trapezoidal (see FIG. 42) depending on the type of the semiconductor structure.

In one embodiment, a liner is formed on the inner side of the STI structure 120.

If the semiconductor structure is PMOS (see FIG. 14), the cross-section of the STI structure 120 is trapezoidal, the angle α between the bottom and the side satisfies 180°>α>90°, and the extension length Sₛₜᵢ of the STI structure satisfies: the half length of the active region>Sₛₜᵢ>0. Preferably, the angle α between the bottom and the side of the cross-section of the STI structure 120 satisfies 135°>α>90°. If the semiconductor structure is NMOS (see FIG. 42), the cross-section of the STI structure 120 is inverted trapezoidal, the angle α between the bottom and the side satisfies 90°>α>0°, and the extension length Sₛₜᵢ of the STI structure satisfies: the half length of the active region>Sₛₜᵢ>0. Preferably, the angle α between the bottom and the side of the cross-section of the STI structure 120 satisfies 45°<α<90°. If the semiconductor structure is PMOS (see FIG. 28), the cross-section of the STI structure 120 is Sigma-shaped, the angle α between the lower bottom and the lower side and the angle β between the upper bottom and the upper side satisfy 180°>α and β>90°, respectively, and the extension length Sₛₜᵢ of the STI structure satisfies: the half length of the active region>Sₛₜᵢ>0. Preferably, the angle α between the lower bottom and the lower side and the angle β between the upper bottom and the upper side of the cross-section of the STI structure 120 satisfy 135°>α and β>90°, respectively.

In one embodiment, the source/drain regions (350) are raised source/drain regions, the shapes of which are square or Sigma-shaped.

For PMOS, the STI structure 120 whose cross-section is is trapezoidal or Sigma-shaped may apply a compressive stress to the channel region of the device, thereby increasing the mobility of the channel carrier. For NMOS, the STI structure 120 whose cross-section is inverted trapezoidal may apply a tensile stress to the channel region of the device, thereby also increasing the mobility of the channel carrier. Therefore, the semiconductor structure of the present invention can increase the mobility of the channel carrier of both PMOS devices and NMOS devices.

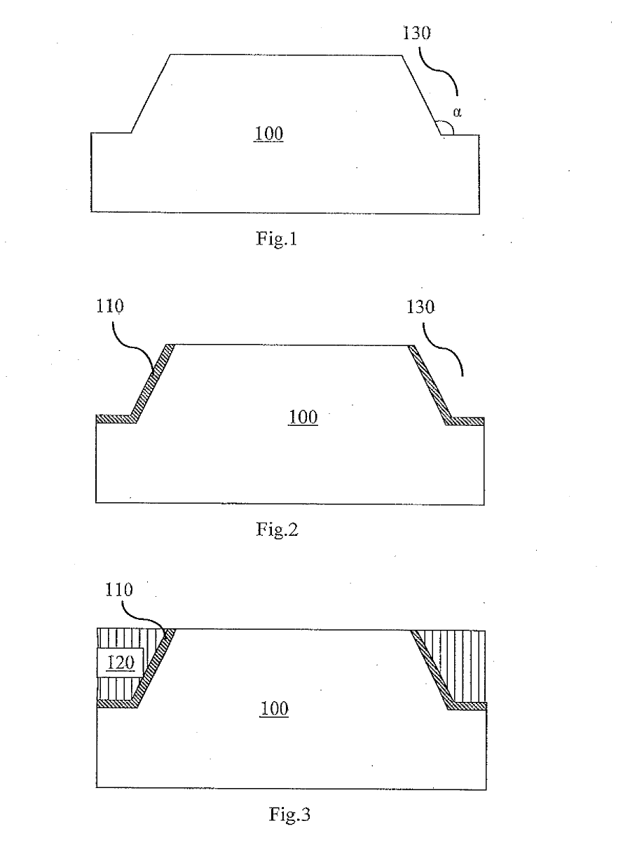

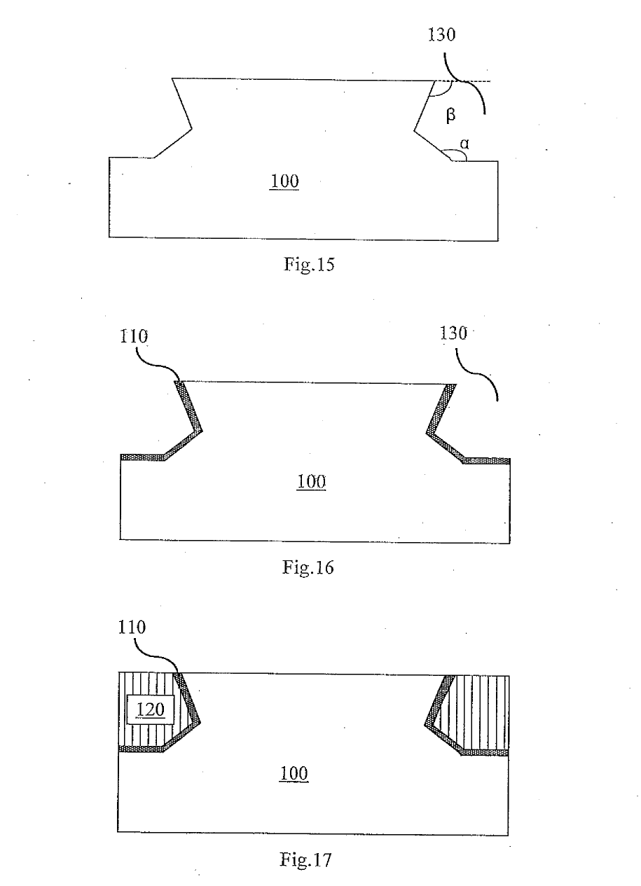

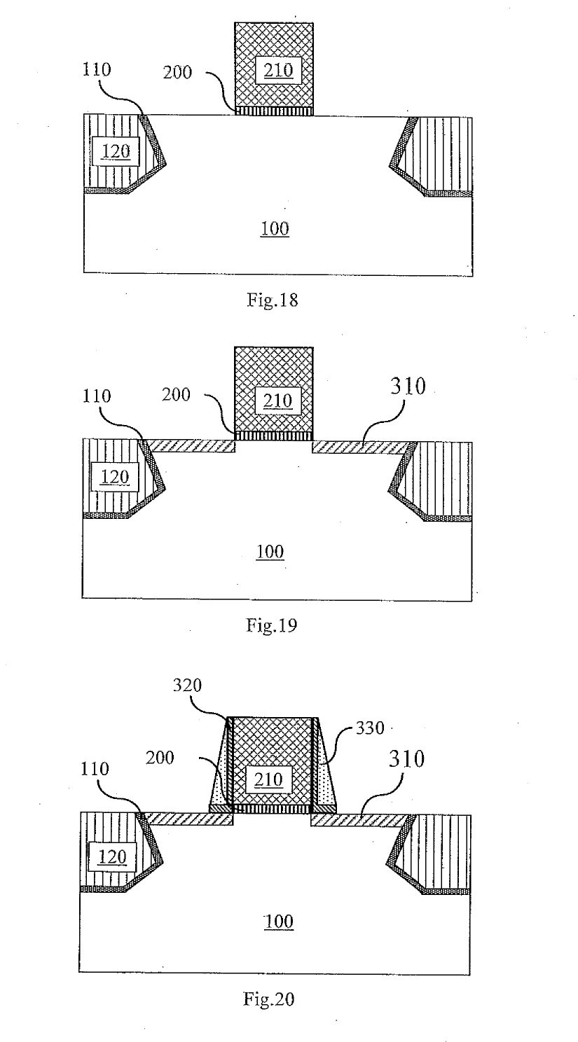

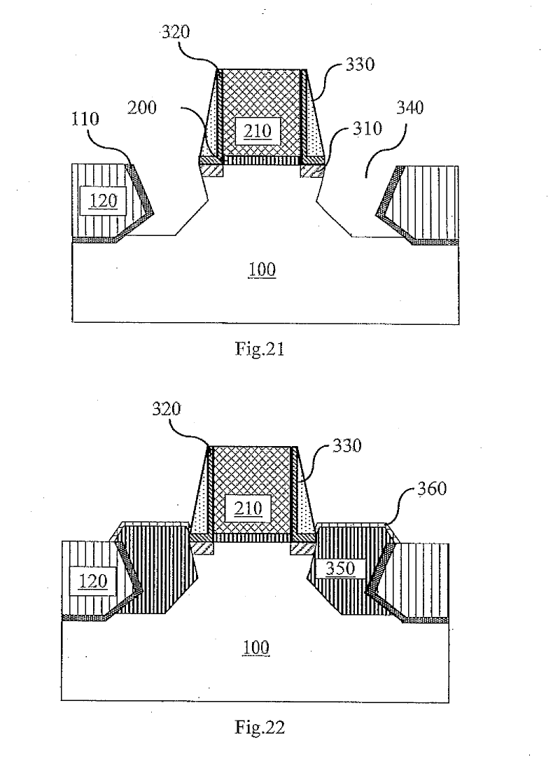

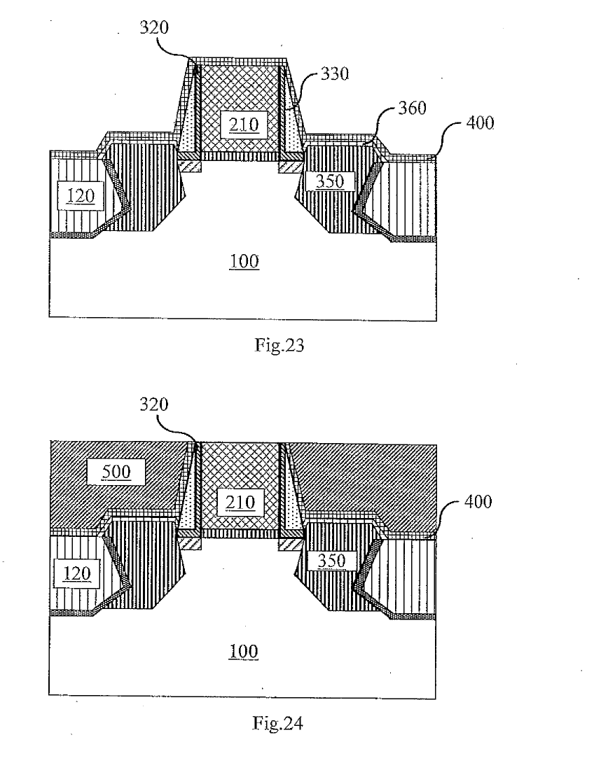

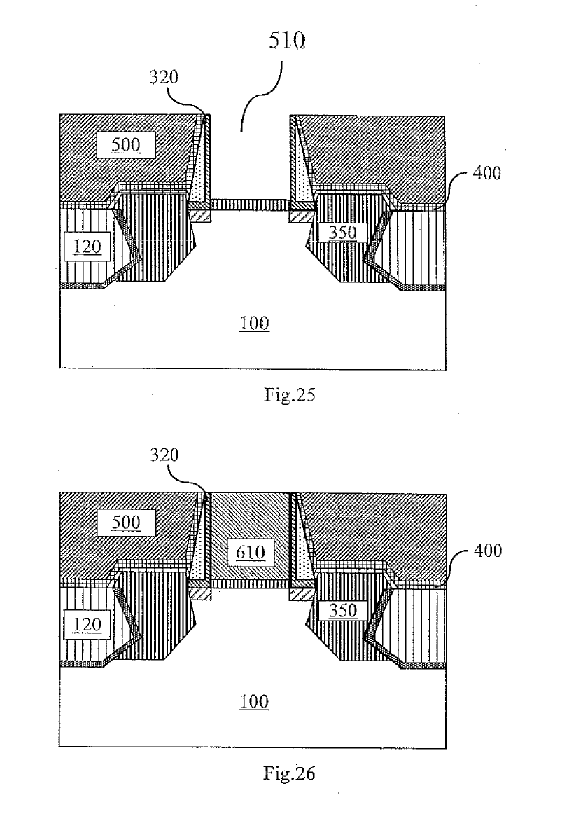

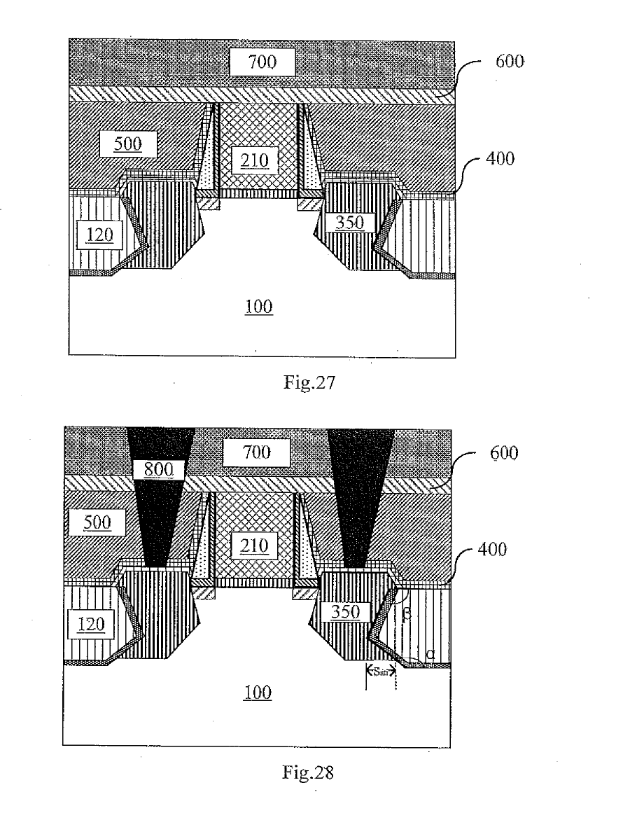

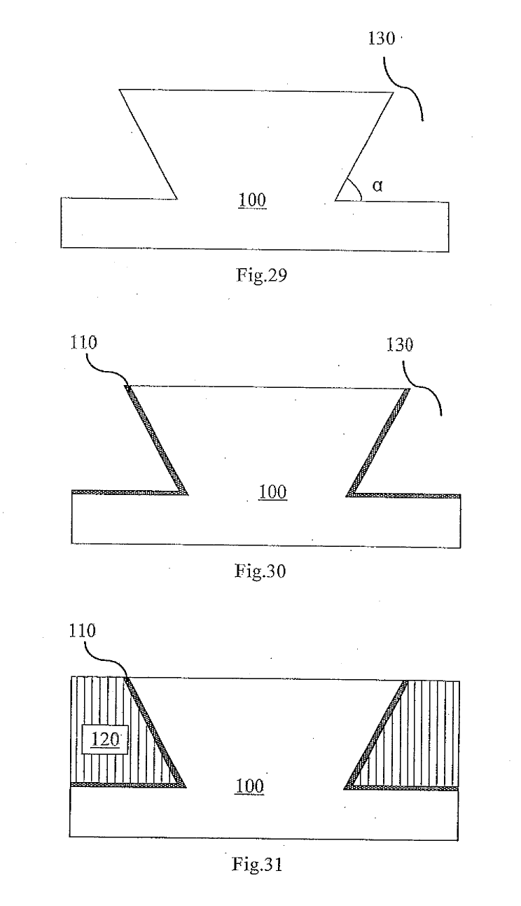

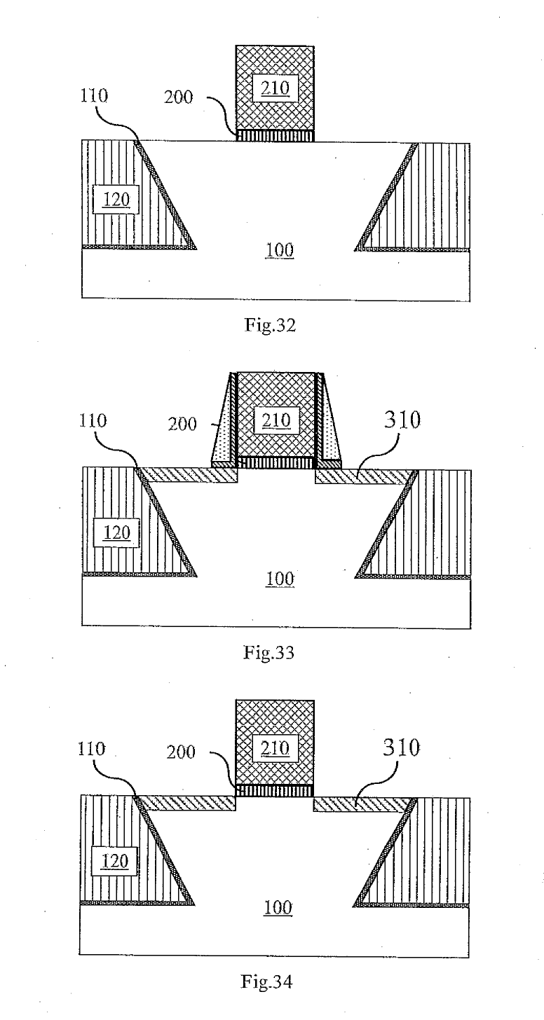

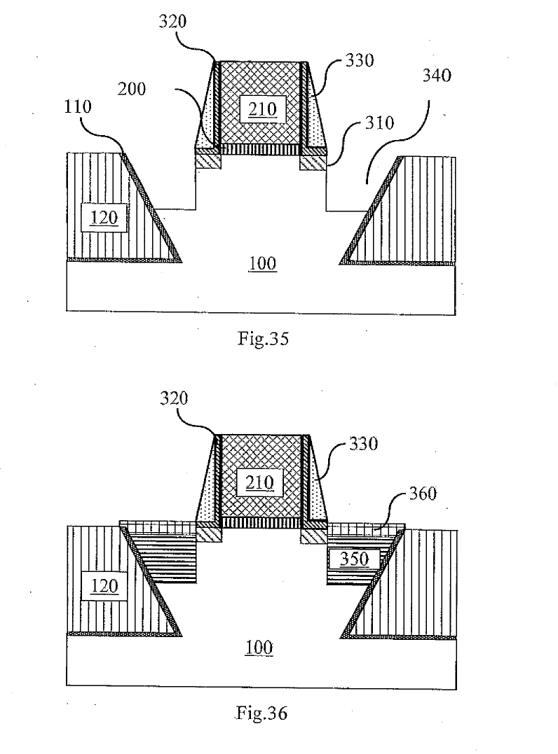

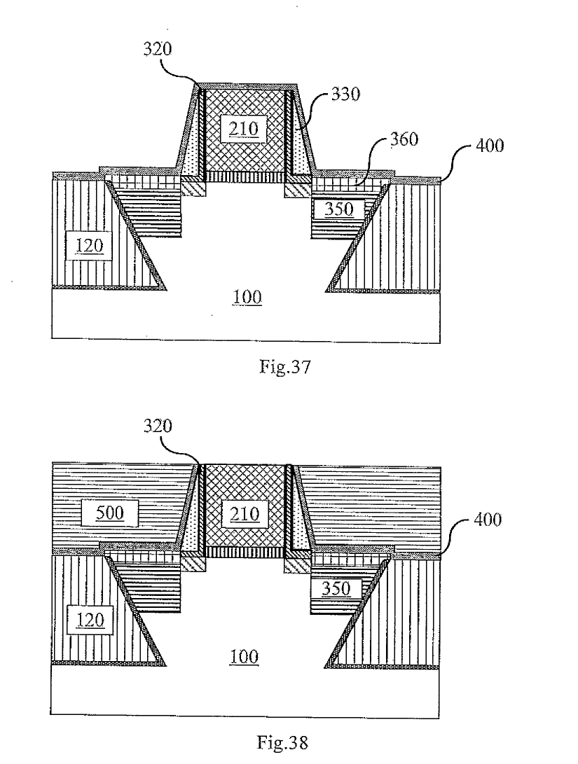

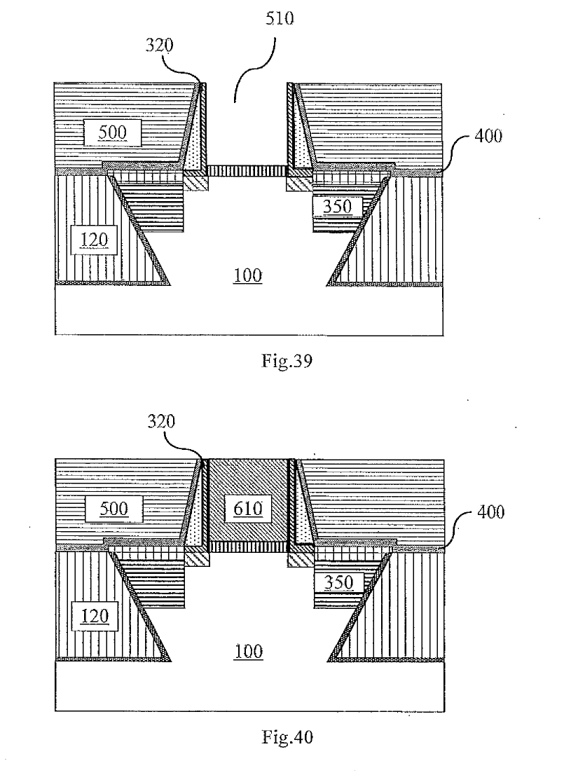

The manufacturing method of the semiconductor structure according to the present invention is described below with reference to FIGS. 1 to 42. FIGS. 1-14 show the manufacturing methods of the embodiments where the semiconductor structure is PMOS and the cross-section of the STI structure 120 is trapezoidal. FIGS. 15-28 show the manufacturing methods of the embodiments where the semiconductor structure is PMOS and the cross-section of the STI structure 120 is Sigma-shaped. FIGS. 29-42 show the manufacturing methods of the embodiments where the semiconductor structure is NMOS and the cross-section of the STI structure 120 is inverted trapezoidal.

First, a substrate 100 is provided.

In this embodiment, the substrate 100 is single crystal silicon. In other embodiments, the substrate layer 100 may further comprise other basic semiconductors such as germanium, or other compound semiconductors such as silicon carbide, gallium arsenide, indium arsenide or indium phosphide. Typically, the thickness of the substrate layer 100 may be, but not limited to, about a few hundred microns, for example, in the range of 0.2 mm to 1 mm.

Then, a plurality of STI structures 120 are formed in the substrate to divide the surface of the substrate into at least one active region, wherein the cross-section of the STI structure is trapezoidal, Sigma-shaped or inverted trapezoidal depending on the type of the semiconductor structure to be formed by the adjacent active region.

In this embodiment, the etching process can be a selective etching method such as reactive ion etching (RIE).

Specifically, if the semiconductor structure to be formed in adjacent active region is PMOS, then a shallow trench 130 whose cross-section is trapezoidal can be formed, as shown in FIG. 1. The reaction gas in RIE contains F-based and Cl-based chemical etching components. Under lower power and greater pressure, pure F-based and Cl-based gases generally exhibit an isotropic selective corrosion. The Cl-based gas is taken as an example, and the F-based gas has a similar property. By adding to Cl₂ a halide gas such as HBr, an anisotropic selective etching can be achieved. Usually, single crystal silicon etching is composed of two steps, i.e., main etching with Cl₂+HBr and overetching with Cl₂+HBr+O₂. The introduction of O₂ into overetching may reduce the production of the reaction polymer so as to improve the isotropy and improve the side steepness of the Cl-based etched silicon trench to achieve anisotropic etching of the approximate angle of 90°. In the steps of forming the trapezoidal shallow trench of the present invention, by adjusting the relative proportion of the main etching time and the overetching time, or adjusting the gas content, power and pressure in each step, the production of the anisotropical etching reaction polymer can be controlled, and the angle α between the side and the bottom of the trapezoide can be further controlled. The more production of the polymer, the smaller the angle α is. For example, with U.S. LAM 4420 etcher, main etching pressure of 150-250 mtor, RF power of 250-300 W, Cl₂ of 50-150 sccm, HBr of 10-30 sccm, the overetching pressure of 250-350 mtor, RF power of 260-300 W, Cl₂ of 50-150 sccm, HBr of 10-30 sccm, He of 30-70 sccm, O₂ of 5-10 sccm, and the main etching time to overetching time ratio of less than 1:0.8, a trapezoidal shallow trench may be achieved, and the angle α between the side and bottom is greater than 90°, as shown in FIG. 1.

In addition, if the semiconductor structure to be formed in the adjacent active region is PMOS, a shallow trench whose cross-section is Sigma-shaped can also be formed. The specific process may include anisotropic dry etching, for example, the above-mentioned RIE etching to form a shallow trench, and then applying the TMAH (tetramethyl ammonium hydroxide solution) crystal orientation selective corrosion to form a Sigma shape with multiple crystalline surfaces, as shown in FIG. 15.

If the semiconductor structure to be formed in the adjacent active region is NMOS, then a shallow trench whose cross-section is inverted trapezoidal can be formed, as shown in FIG. 29. The inverted trapezoidal cross section can be formed by adjusting the dry etching conditions, such as gas composition, power, pressure, and etching rate, to gradually increase the anisotropy ratio.

Specifically, by gradually increasing the gas flow, increasing the pressure and reducing the power so as to gradually increase the lateral etching amount (the lateral etched thickness) of isotropic etching with the proceeding of the etching, the inverted trapezoid with α<90° is formed based on the common vertical etching. For example, the angle α between side edge and bottom edge of the inverted trapezoid may be close to 45° with the pressure of 350-500 mtor, Cl₂ of 150-300 sccm, and O₂ of 10-30 sccm, as shown in FIG. 29.

In addition, through this embodiment, those skilled in the art may easily conceive that the cross-section of the shallow trench is not limited to trapezoidal or Sigma-shaped, but includes other shapes which is may enable manipulation of stress in the active region among the adjacent STI structures, e.g., the side is not linear, but has a certain curvature (concave or outside concave).

After the STI structure having a trapezoidal, Sigma-shaped or inverted trapezoidal cross-section is formed, a liner 110 is formed in the trench 130 prior to filling of the trench insulating material, as shown in FIGS. 2, 16 and 30.

The liner can be formed by oxidation or deposition, where the deposition materials can be one of Ta, TaN, Ti, TiN and Ru, or any combination thereof. The liner can have a thickness of 2-15 nm. The liner 110 can release the stress generated during the STI etching process.

Afterwards, the HDP (High Density Plasma) process can be used for filling of the trench insulation material selected from SiO₂, Si₃N₄, and F-doped low-stress dielectric, etc. The above process of forming different liners and filling of different trench insulating material can easily regulate the magnitude of the stress to the active region, thus regulating the stress in the channel region of the MOS transistor to be formed in the active region later. Thus, the STI structure 120 which can apply a first stress to the channel can be formed, as shown in FIGS. 3, 17 and 31.

In short, the shape of the shallow trench is adjusted by controlling the etching parameters and filling of different trench insulating materials which can easily adjust the magnitude of the stress to the active region, thereby regulating the stress in the channel region of the MOS transistor to be formed in the active region later. At the same time, combination with other stress mechanisms may obtain desired channel stress.

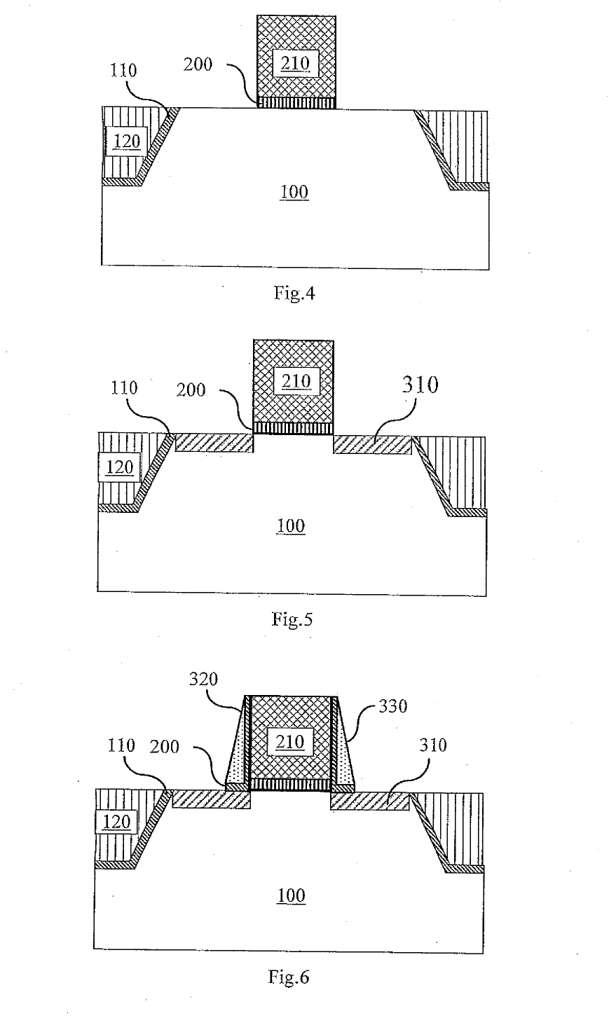

Subsequently, a gate stack and source/drain regions corresponding to the type of the semiconductor structure to be formed can be formed on the active region, as shown in FIGS. 4-14, 18-28 and 32-42. For example, they can be formed by a gate-first process or a gate-last process. The examples in FIGS. 4-14, 18-28 and 32-42 show the general process of the gate-last process.

First, a gate dielectric layer 200 is formed on the substrate 100. In this embodiment, the gate dielectric layer 200 can be formed from silicon oxide, silicon nitride, or any combination thereof. In other embodiments, it can also be a high-K dielectric, for example, one of HfO₂, HfSiO, HfSiON, HfTaO, HfTiO, HfZrO, Al₂O₃, La₂O₃, ZrO₂, LaAlO or any combination thereof with a thickness of 2 nm to 10 nm. Then, a dummy gate 210 is formed on the gate dielectric layer 200, for example, by depositing a polycrystalline silicon, polycrystalline SiGe, amorphous silicon, and/or doped or undoped silicon oxide and silicon nitride, silicon oxynitride, silicon carbide, or even metal. In another embodiment, the dummy gate stack can also have a dummy gate only and have no gate dielectric layer 200, where the gate dielectric layer is formed by removing the dummy gate in the subsequent replacement gate process.

Then, source/drain regions can be formed on both sides of the dummy gate stack.

The source/drain extension 310 can be first formed in the substrate 100 on both sides of dummy gate stack.

Specifically, as shown in FIGS. 5, 19 and 33, the dummy gate stack is used as a mask to form a shallow source/drain extension 310 by ion implantation, e.g., implanting P-type or N-type dopants or impurities into the substrate 100. For PMOS, the source/drain extension can be P-type doped; and for NMOS, the source/drain extension can be N-type doped. The specific processes of the ion implantation operation, is such as implantation energy, implantation dose, implantation times and doping particles can be flexibly adjusted according to the product design.

Afterwards, source/drain regions 350 can be formed in the substrate 100 on both sides of the source/drain extension 310.

Specifically, as shown in FIGS. 6, 20 and 34, first of all, an offset spacer 320 is formed on the substrate 100, where the offset spacer 320 surrounds the sidewall of the dummy gate stack. Part of the substrate 100 on both sides of the dummy gate stack is covered by the offset spacer 320. The materials of the offset spacer 320 include silicon nitride, silicon oxide, silicon oxynitride, silicon carbide, or any combination thereof, and/or other suitable materials. Then, the spacer 330 surrounding the offset spacer 320 is formed, wherein the material of the spacer 330 is different from the insulating material of the offset spacer 320.

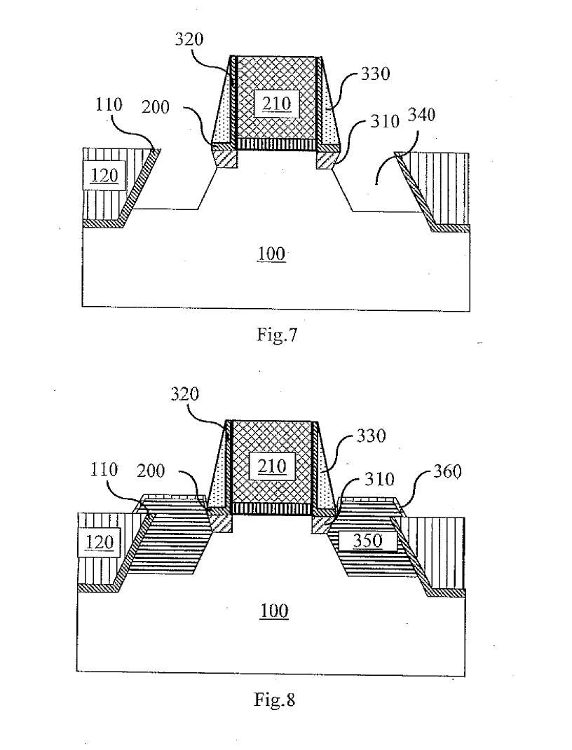

Then, as shown in FIGS. 7, 21 and 35, the dummy gate stack with an offset spacer 320 and a spacer 330 is used as a mask, the substrate 100 on both sides of the spacer 330 is etched by anisotropic dry etching and/or wet etching to form a trench 340. The wet etching process includes tetramethyl ammonium hydroxide (TMAH), potassium hydroxide (KOH) or other suitable etching solution; and the dry etching process includes sulfur hexafluoride (SF₆), hydrogen bromide (HBr), hydrogen iodide (HI), chlorine, argon, helium and any combination thereof, and/or other suitable materials. After the trench 340 is formed, as shown in FIGS. 8, 22 and 36, the substrate 100 is used as a seed to fill the trench 340 by processes such as epitaxial growth. Preferably, the lattice constant of the material for forming source/drain regions 350 is not equal to that of the material of the substrate 100. For PMOS devices, the lattice constant of the source/drain regions 350 is slightly greater than that of the substrate 100, and thus may apply a compressive stress to the channel, e.g., as for Si_{1-X}Ge_{X}, X ranges from 0.1 to 0.7, such as 0.2, 0.3, 0.4, 0.5 or 0.6; for NMOS devices, the lattice constant of the source/drain regions 350 is slightly less than that of the substrate 100, and thus may apply a tensile stress to the channel, e.g., as for Si:C, the atomic percentage of C ranges from 0.2% to 2%, e.g., 0.5%, 1% or 1.5%. After the trench 340 is filled, the source/drain regions 350 can be formed by processes such as ion implantation or in-situ doping. Alternatively, the source/drain regions 350 can be formed by in-situ doping during the process of epitaxial growth. As for Si_{1-X}Ge_{X}, the doping impurity is boron; and as for Si:C, the doping impurity is phosphorus or arsenic.

In other embodiments, the source/drain regions can also be formed on both sides of the dummy gate stack by implanting P-type or N-type dopants or impurities into the substrate 100.

Then, the semiconductor structure is subject to annealing so as to activate the dopants in the source/drain regions 310. Annealing can be performed by using rapid annealing, spike annealing and other appropriate methods. Of course, the semiconductor structure can also be annealed after the source/drain extension has been formed.

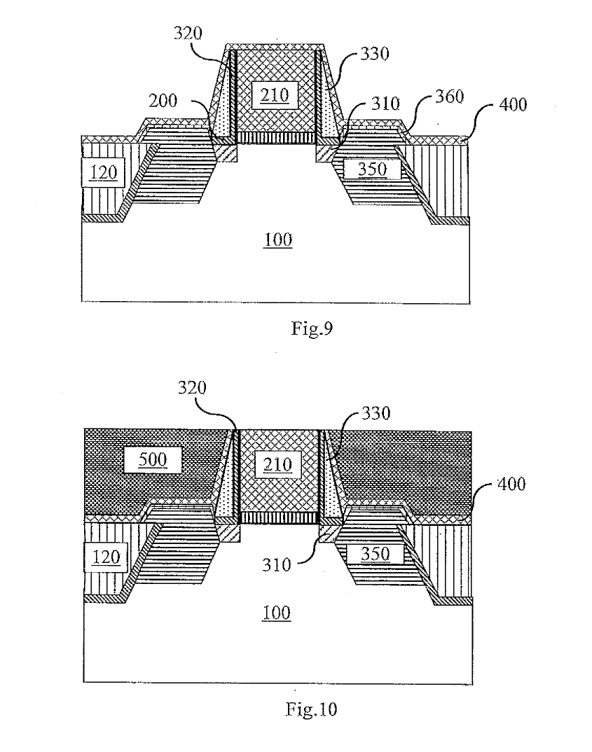

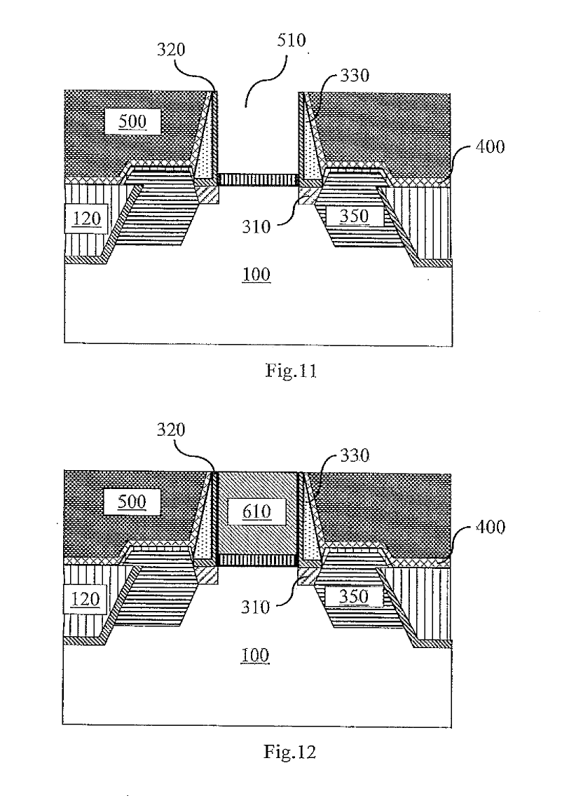

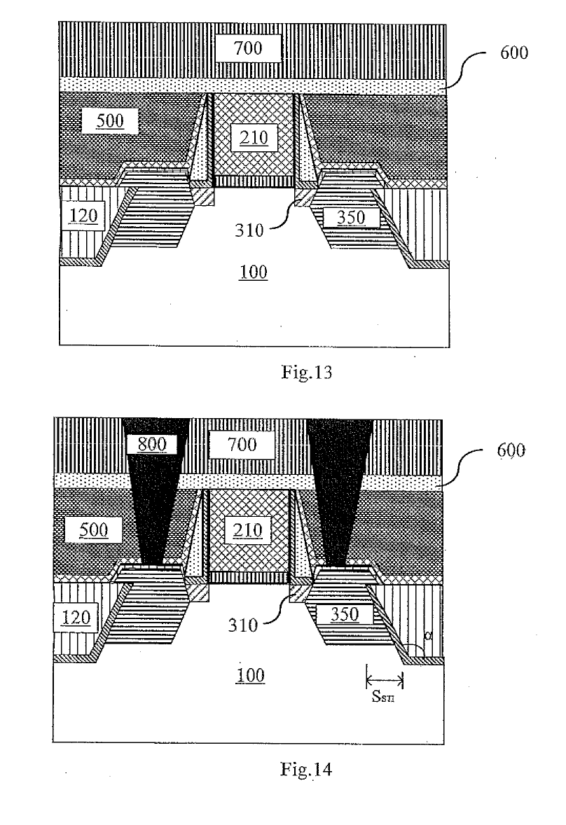

Subsequently, the manufacturing of the semiconductor structure is completed in accordance with the conventional manufacturing process steps (please refer to FIGS. 8, 22, 36 to FIGS. 14, 28, 42). Specifically, as shown in FIGS. 8, 22, and 36, a metal silicide layer 360 is formed on the surface of the source/drain regions 310 to reduce contact resistance. As shown in FIGS. 9, 23 and 37, a contact etch stop layer 400 is formed on the semiconductor structure; then, as shown in FIGS. 10, 24 and 38, the first interlayer dielectric layer 500 is deposited and subject to planarization operation to expose the dummy gate 210; then, as shown in FIGS. 11, 25, and 39, the dummy gate 210 is removed to form a second trench 510; then, as shown in FIGS. 12, 26, and 40, a gate electrode layer 610 is formed in the second trench 510; and then, as shown in FIGS. 13, 27 and 41 and FIGS. 14, 28 and 42, a cap layer 600 and a second interlayer dielectric layer 700 are formed on the first interlayer dielectric layer 500, and a contact plug 800 is formed throughout the second interlayer dielectric layer 700, the cap layer 600 and the first interlayer dielectric layer 500.

Although the exemplified embodiments and the advantages thereof have been illustrated in detail, it is understood that any modification, replacement and change can be made to these embodiments without departing from the spirit of the invention and the scope defined in the attaching claims. As to other examples, a person skilled in the art can easily understand that the order of the process steps can be modified without falling outside the protection scope of the invention.

In addition, the application fields of the invention are not limited to the processes, mechanism, fabrication, material composition, means, methods and steps in the particular embodiments as given in the description. From the disclosure of the invention, a person skilled in the art can easily understand that, as for the processes, mechanism, fabrication, material composition, means, methods or steps present or to be developed, which are carried out to realize substantially the same function or obtain substantially the same effects as the corresponding examples described according to the invention, such processes, mechanism, fabrication, material composition, means, methods or steps can be applied according to the invention. Therefore, the claims attached to the invention are intended to encompass the processes, mechanism, fabrication, material composition, means, methods or steps is into the protection scope thereof.

1. A semiconductor structure, comprising:
a substrate;
a gate stack located on the substrate, and comprising at least a gate dielectric layer and a gate electrode layer;
source/drain regions located in the substrate on both sides of the gate stack; and
Shallow Trench Isolation (STI) structures located in the substrate on both sides of the source/drain regions, wherein depending on the type of the semiconductor structure, the cross-section of the STI structures are trapezoidal, Sigma-shaped or inverted trapezoidal.

2. The semiconductor structure according to claim 1, wherein a liner is formed on outer side of the STI structure.

3. The semiconductor structure according to claim 1, wherein:
if the semiconductor structure is PMOS, then the cross-section of the STI structure is trapezoidal, the angle α between the bottom and the side satisfies 180°>α>90°, and the extension length Sₛₜᵢ of the STI structure satisfies: the half length of the active region>Sₛₜᵢ>0.

4. The semiconductor structure according to claim 3, wherein:
the angle α between the bottom and the side of the cross-section of the STI structure satisfies 135°>α>90°.

5. The semiconductor structure according to claim 1, wherein:
if the semiconductor structure is NMOS, then the cross-section of the STI structure is inverted trapezoidal, the angle α between the bottom and the side satisfies 90°>α>0°, and the extension length Sₛₜᵢ of the STI structure satisfies: the half length of the active region>Sₛₜᵢ>0.

6. The semiconductor structure according to claim 5, wherein:
the angle α between the bottom and the side of the cross-section of the STI structure satisfies 45°<α<90°.

7. The semiconductor structure according to claim 1, wherein:
if the semiconductor structure is PMOS, then the cross-section of the STI structure is Sigma-shaped, the angle α between theits lower bottom edge and the lower side and the angle β between the upper bottom and the upper side satisfy 180°>α and β>90°, respectively, and the extension length Sₛₜᵢ of the STI structure satisfies: the half length of the active region>Sₛₜᵢ>0.

8. The semiconductor structure according to claim 7, wherein:
the angle α between the lower bottom and the lower side and the angle β between the upper bottom and the upper side of the cross-section of the STI structure satisfy 135°>α and β>90°, respectively.

9. The semiconductor structure according to claim 1, wherein:
the source/drain regions are raised source drain regions, and the shapes of which are square or Sigma-shaped.

10. A method for manufacturing a semiconductor structure, comprising:
providing a substrate;
forming a plurality of STI structures in the substrate to divide the substrate surface into at least one active region, wherein the cross-section of the STI structures are trapezoidal, Sigma-shaped or inverted trapezoidal depending on the type of semiconductor structures to be formed in adjacent active regions; and
forming a gate stack and source/drain regions corresponding to the type of the semiconductor structure to be formed on a respective active region.

11. The method according to claim 10, wherein forming a plurality of STI structures includes forming a plurality of trenches in the substrate by an etching process and filling the plurality of trenches with a trench insulating material.

12. The method according to claim 11, wherein a liner is formed on inner side of the trench before filling the trench insulating material.

13. The method according to claim 11, wherein the etching process is RIE.

14. The method according to claim 13, wherein:
if the semiconductor structures to be formed in adjacent active regions are PMOS, the reaction gas in the RIE has an isotropic etching capability; and by controlling the yield of polymers from the isotropical etching reaction, the trench is etched to be trapezoidal, the angle α between the bottom and the side satisfies 180°>α>90°, and the extension length Sₛₜᵢ of the STI structure satisfies: the half length of the active region>Sₛₜᵢ>0.

15. The method according to claim 14, wherein the angle α between the bottom and the side of the trapezoidal trench satisfies: 135°>α>90°.

16. The method according to claim 13, wherein:
if the semiconductor structures to be formed in the adjacent active regions are NMOS, the reaction gas in the RIE has an anisotropic etching capability; and by controlling the yield of polymers from the anisotropical etching reaction, the trench is inverted trapezoidal, the angle α between the bottom and the side satisfies 90°>α>0°, and the extension length Sₛₜᵢ of the STI structure satisfies: the half length of the active region>Sₛₜᵢ>0.

17. The method according to claim 16, wherein the angle α between the bottom and the side of the inverted trapezoidal trench satisfies: 45°<α<90°.

18. The method according to claim 13, wherein:
if the semiconductor structures to be formed in adjacent active regions re PMOS, the reaction gas in the RIE has an anisotropic etching capability; by controlling the yield of polymers from the anisotropical etching reaction, the trench is etched to be Sigma-shaped, the angle α between the lower bottom and the lower side and the angle β between the upper bottom and the upper side satisfy 180°>α and β>90°, respectively, and the extension length Sₛₜᵢ of the STI structure satisfies: the half length of the active region>Sₛₜᵢ>0.

19. The method according to claim 18, wherein:
the angles α and β between the bottom and the side of the Sigma-shaped trench satisfy 135°>α and β>90°, respectively.

20. The method according to claim 12, wherein:
the trench insulating material for filling is SiO₂ or Si₃N₄.
